(19) United States
(12) Patent Application Publication
(10) Pub. No.: US 2015/0021699 A1
(43) Pub. Date: Jan. 22, 2015

(54) FIN Field Effect Transistors Having Multiple Threshold Voltages

(71) Applicant: International Business Machines Corporation, Armonk, NY (US)

(72) Inventors: Takashi Ando, Tuckahoe, NY (US); Michael P. Chudzik, Danbury, CT (US); Balaji Kannan, Fishkill, NY (US); Siddarth A. Krishnan, Peekskill, NY (US); Unoh Kwon, Fishkill, NY (US); Vijay Narayanan, New York, NY (US)

(21) Appl. No.: 13/945,095

(22) Filed: Jul. 18, 2013

(51) Int. Cl. H01L 27/088; H01L 21/28

(52) U.S. Cl. CPC H01L 27/0886; H01L 21/28008
USPC 257/368; 438/591

(57) ABSTRACT

A high dielectric constant (high-k) gate dielectric layer is formed on semiconductor fins including one or more semiconductor materials. A patterned diffusion barrier metallic nitride layer is formed to overlie at least one channel, while not overlying at least another channel. A threshold voltage adjustment oxide layer is formed on the physically exposed portions of the high-k gate dielectric layer and the diffusion barrier metallic nitride layer. An anneal is performed to drive in the material of the threshold voltage adjustment oxide layer to the interface between the intrinsic channel(s) and the high-k gate dielectric layer, resulting in formation of threshold voltage adjustment oxide portions. At least one workfunction material layer is formed, and is patterned with the high-k gate dielectric layer and the threshold voltage adjustment oxide portions to form multiple types of gate stacks straddling the semiconductor fins.

### RELATED APPLICATIONS

The present application is related to a copending U.S. patent application Ser. No. ______ (Attorney Docket No. FIS920130044US1; 29851), the entire contents of which are incorporated herein by reference.

### BACKGROUND

The present disclosure generally relates to semiconductor devices, and particularly to fin field effect transistors having different threshold voltages through gate dielectric stack modification, and methods of manufacturing the same.

Fin field effect transistors are employed to overcome shortcomings of planar fin field effect transistors, which include limited on-current per unit area. Because manufacturing of semiconductor fins having different heights requires additional processing steps, an effective method of controlling the on-current of fin field effect transistors without resorting to multiple fin heights is desired.

### SUMMARY

Multiple types of gate stacks can be formed on semiconductor fins. A high dielectric constant (high-k) gate dielectric layer is formed on the semiconductor fins. A diffusion barrier metallic nitride layer is deposited and patterned to block at least one portion of the high-k gate dielectric layer, while physically exposing at least another portion of the high-k gate dielectric layer. A threshold voltage adjustment oxide layer is formed on the physically exposed portions of the high-k gate dielectric layer and the diffusion barrier metallic nitride layer. An anneal is performed to drive in the material of the threshold voltage adjustment oxide layer to the interface between the intrinsic channel(s) and the high-k gate dielectric layer, resulting in formation of threshold voltage adjustment oxide portions. At least one workfunction material layer is formed, and is patterned with the high-k gate dielectric layer and the threshold voltage adjustment oxide portions to form gate stacks straddling the semiconductor fins.

According to an aspect of the present disclosure, a semiconductor structure contains a first fin field effect transistor including a first gate stack, a second fin field effect transistor including a second gate stack, and a third fin field effect transistor including a third gate stack. The first gate stack includes, from bottom to top, a first high dielectric constant (high-k) dielectric portion containing a first high-k dielectric material having a dielectric constant greater than 4.0 and straddling a first semiconductor fin, and a first gate electrode contacting the first high-k dielectric portion. The second gate stack includes, from bottom to top, a threshold voltage adjustment oxide portion containing another dielectric material having a second high-k dielectric constant greater than 4.0 and different from the first high-k dielectric material and straddling a second semiconductor fin, a second high-k dielectric portion including the first high-k dielectric material, and a second gate electrode contacting the second high-k dielectric portion. The third gate stack includes at least, from bottom to top, a third high-k dielectric portion containing the first high-k dielectric material and straddling a third semiconductor fin, and a third gate electrode contacting the third high-k dielectric portion. The first and second fin field effect transistors can be transistors of a first conductivity type, and the third fin field effect transistor can be a transistor of a second conductivity type that is the opposite of the first conductivity type.

According to another aspect of the present disclosure, a method of forming a semiconductor structure is provided. A high dielectric constant (high-k) dielectric layer including a first high-k dielectric material having a dielectric constant greater than 4.0 is formed on a plurality of semiconductor fins. A diffusion barrier metallic nitride layer is formed and patterned such that at least one portion of the high-k dielectric layer is physically exposed while at least another portion of the high-k dielectric layer is covered by a patterned portion of the diffusion barrier metallic nitride layer. A threshold voltage adjustment oxide layer including a second high-k dielectric material having another dielectric constant greater than 4.0 is formed over the high-k dielectric layer and the patterned diffusion barrier metallic nitride layer. Diffusion of the second high-k dielectric material through the first high-k dielectric material is induced by an anneal. The patterned diffusion barrier layer blocks diffusion of the second high-k dielectric material therethrough and at least one threshold voltage adjustment oxide portion is formed directly on at least one of the plurality of semiconductor material stacks. The patterned diffusion barrier metallic nitride layer is removed. At least one conductive material layer is formed on the high-k dielectric layer. Gate stacks are formed by patterning the at least one conductive material layer, the high-k dielectric layer, and the at least one threshold voltage adjustment oxide portion.

### BRIEF DESCRIPTION OF SEVERAL VIEWS OF THE DRAWINGS

FIG. 1 is a vertical cross-sectional view of a first exemplary semiconductor structure after formation of semiconductor fins according to a first embodiment of the present disclosure.

FIG. 2 is a vertical cross-sectional view of the first exemplary semiconductor structure after formation of disposable gate stacks, gate spacers, and source and drain regions according to a first embodiment of the present disclosure.

FIG. 2A is a top-down view of the first exemplary semiconductor structure of FIG. 2.

FIG. 3 is a vertical cross-sectional view of the first exemplary semiconductor structure after removal of disposable gate stacks and formation of gate cavities according to the first embodiment of the present disclosure.

FIG. 4 is a vertical cross-sectional view of the first exemplary semiconductor structure after deposition of a high dielectric constant (high-k) gate dielectric layer and a diffusion barrier metallic nitride layer according to the first embodiment of the present disclosure.

FIG. 5 is a vertical cross-sectional view of the first exemplary semiconductor structure after patterning of the diffusion barrier metallic nitride layer according to the first embodiment of the present disclosure.

FIG. 6 is a vertical cross-sectional view of the first exemplary semiconductor structure after deposition of a threshold voltage adjustment oxide layer and optional deposition of a cap material layer according to the first embodiment of the present disclosure.

FIG. 7 is a vertical cross-sectional view of the first exemplary semiconductor structure after an anneal that forms threshold voltage adjust oxide portions between intrinsic channels and the high-k gate dielectric layer and after removal of the optional cap material layer and the patterned diffusion barrier metallic nitride layer according to the first embodiment of the present disclosure.

FIG. 8 is a vertical cross-sectional view of the first exemplary semiconductor structure after deposition and patterning of a first workfunction material layer and deposition of a second workfunction material layer according to the first embodiment of the present disclosure.

FIG. 9 is a vertical cross-sectional view of the first exemplary semiconductor structure after planarization of workfunction material layers and dielectric material layers from above a top surface of a planarization dielectric layer according to the first embodiment of the present disclosure.

FIG. 10 is a vertical cross-sectional view of the first exemplary semiconductor structure after formation of a contact level dielectric layer and various contact via structures according to the first embodiment of the present disclosure.

FIG. 11 is a vertical cross-sectional view of a variation of the first exemplary semiconductor structure according to a second embodiment of the present disclosure.

FIG. 12 is a vertical cross-sectional view of a second exemplary semiconductor structure after deposition of a high dielectric constant (high-k) gate dielectric layer and a diffusion barrier metallic nitride layer and patterning of the diffusion barrier metallic nitride layer according to a second embodiment of the present disclosure.

FIG. 13 is a vertical cross-sectional view of the second exemplary semiconductor structure after deposition of a threshold voltage adjustment oxide layer and optional deposition of a cap material layer according to the second embodiment of the present disclosure.

FIG. 14 is a vertical cross-sectional view of the second exemplary semiconductor structure after an anneal that forms threshold voltage adjust oxide portions between intrinsic channels and the high-k gate dielectric layer according to the second embodiment of the present disclosure.

FIG. 15 is a vertical cross-sectional view of the second exemplary semiconductor structure after deposition and patterning of a second workfunction material layer and deposition of a second workfunction material layer according to the second embodiment of the present disclosure.

FIG. 16 is a vertical cross-sectional view of the second exemplary semiconductor structure after formation of gate stacks according to a second embodiment of the present disclosure.

FIG. 17 is a vertical cross-sectional view of the second exemplary semiconductor structure after formation of gate spacers and source and drain regions according to the second embodiment of the present disclosure.

FIG. 18 is a vertical cross-sectional view of the second exemplary semiconductor structure after formation of a contact level dielectric layer and various contact via structures according to the second embodiment of the present disclosure.

FIG. 19 is a vertical cross-sectional view of a variation of the second exemplary semiconductor structure according to a variation of the second embodiment of the present disclosure.

### DETAILED DESCRIPTION

As stated above, the present disclosure relates to fin field effect transistors having different threshold voltages through gate dielectric stack modification, and methods of manufacturing the same. Aspects of the present disclosure are now described in detail with accompanying figures. Like and corresponding elements are referred to by like reference numerals. Proportions of various elements in the accompanying figures are not drawn to scale. As used herein, ordinals such as “first” and “second” are employed merely to distinguish similar elements, and different ordinals may be employed to designate a same element in the specification and/or claims.

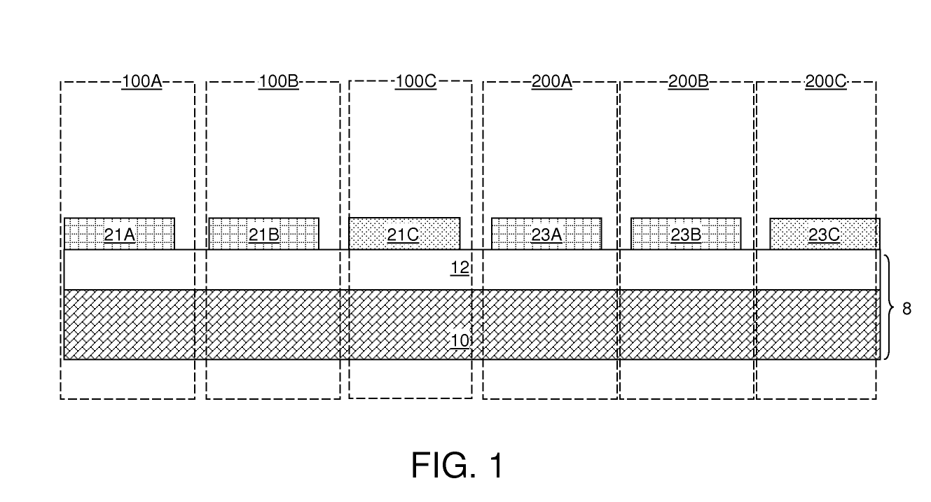

Referring to FIG. 1, a first exemplary semiconductor structure according to a first embodiment of the present disclosure includes a plurality of semiconductor fins located on a substrate. In one embodiment, the plurality of semiconductor fins can be formed by providing a semiconductor-on-insulator (SOI) substrate including a vertical stack, from bottom to top, of a handle substrate 10, a buried insulator layer 12, and a top semiconductor layer, and by patterning the top semiconductor layer to form the plurality of semiconductor fins. The top semiconductor layer can include a same semiconductor material throughout, or can include a plurality of regions including different semiconductor materials. Alternatively, a bulk semiconductor substrate can be employed in lieu of an SOI substrate to provide a plurality of semiconductor fins located on a semiconductor substrate, i.e., the remaining portion of the bulk semiconductor substrate excluding the plurality of semiconductor fins.

As used herein, a “semiconductor fin” refers to a semiconductor material portion having a pair of parallel vertical sidewalls that are laterally spaced by a uniform dimension. In one embodiment, each semiconductor fin can have a rectangular horizontal cross-sectional area such that the spacing between the pair of parallel vertical sidewalls is the same as the length of shorter sides of the shape of the rectangular horizontal cross-sectional area.

The first exemplary semiconductor structure can include various device regions. In a non-limiting illustrative example, the first exemplary semiconductor structure can include a first device region 100A, a second device region 100B, a third device region 100C, a fourth device region 200A, a fifth device region 200B, and a sixth device region 200C. Additional device regions (not shown) can be provided for the purpose of forming additional devices. Further, multiple instances of devices can be formed in each of the device regions (100A, 100B, 100C, 200A, 200B, 200C). Each of the device regions (100A, 100B, 100C, 200A, 200B, 200C) includes at least one semiconductor fin. The first-type device regions (100A, 100B, 100C) can be employed to form first-type fin field effect transistors, and the second-type device regions (200A, 200B, 200C) can be employed to form second-type fin field effect transistors. Thus, the first, second, and third field effect transistors can be first-type field effect transistors, and the fourth, fifth, and sixth field effect transistors can be second-type field effect transistors. In one embodiment, the first-type can be p-type and the second-type can be n-type. In another embodiment, the first-type can be n-type and the second-type can be p-type.

As used herein, a “fin field effect transistor” refers to a field effect transistor in which at least a channel region is located within a semiconductor fin. As used herein, the term “first-type” and the “second-type” are employed to differentiate between elements employed for p-type devices and elements employed for n-type devices. In one embodiment, “first-type” elements can be elements for p-type planar fin field effect transistors and “second-type” elements can be elements for n-type planar fin field effect transistors. Alternatively, “first-type” elements can be elements for n-type planar fin field effect transistors and “second-type” elements can be elements for p-type planar fin field effect transistors. First-type fin field effect transistors and second-type fin field effect transistors are fin field effect transistors of complementary types, i.e., opposite types that can be employed to form complementary metal oxide semiconductor (CMOS) devices. Thus, p-type fin field effect transistors are fin field effect transistors of the complementary type with respect to n-type fin field effect transistors, and vice versa.

In one embodiment, each of device regions (100A, 100B, 100C, 200A, 200B, 200C) can include at least one semiconductor fin. For example, the first device region 100A can include a first semiconductor fin 21A, the second device region 100B can include a second semiconductor fin 21B, the third device region 100C can include a third semiconductor fin 21C, the fourth device region 200A can include a fourth semiconductor fin 23A, the fifth device region 200B can include a fifth semiconductor fin 23B, and the sixth device region 200C can include a sixth semiconductor fin 23C. In one embodiment, the entirety of the each semiconductor fin (21A, 21B, 21C, 23A, 23B, 23C) can include a same single crystalline semiconductor material. The semiconductor material for the at least one semiconductor fin (21A, 21B, 21C, 23A, 23B, 23C) in each device region (100A, 100B, 100C, 200A, 200B, 200C) can be independently selected. In one embodiment, each semiconductor fin (21A, 21B, 21C, 23A, 23B, 23C) can include a same semiconductor material throughout the entirety of the semiconductor fin (21A, 21B, 21C, 23A, 23B, or 23C). In one embodiment, each semiconductor material for any one of the semiconductor fins (21A, 21B, 21C, 23A, 23B, 23C) can be independently selected from single crystalline silicon, a single crystalline silicon-germanium alloy, a single crystalline silicon-carbon alloy, and a single crystalline silicon-germanium-carbon alloy.

In one embodiment, each semiconductor fin (21A, 21B, 21C, 23A, 23B, 23C) can include an intrinsic single crystalline semiconductor material. Alternately, one or more of the semiconductor fins (21A, 21B, 21C, 23A, 23B, 23C) can include a doped semiconductor material. In one embodiment, each of the first-type semiconductor fins (21A, 21B, 21C) can be intrinsic or can have a doping of a first conductivity type, and each of the second-type semiconductor fins (23A, 23B, 23C) can be intrinsic or can have a doping of a second conductivity type, which is the opposite of the first conductivity type. For example, the first conductivity type can be p-type and the second conductivity type can be n-type, or vice versa.

Each semiconductor fin (21A, 21B, 21C, 23A, 23B, 23C) can include a semiconductor material that is independently selected from silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. In one embodiment, each semiconductor fin (21A, 21B, 21C, 23A, 23B, 23C) can include a semiconductor material that is independently selected from single crystalline silicon, a single crystalline silicon-germanium alloy, a single crystalline silicon-carbon alloy, and a single crystalline silicon-germanium-carbon alloy. As used herein, a “semiconductor material” of an element refers to all elemental or compound semiconductor materials in the element excluding the electrical dopants therein. The semiconductor material within each semiconductor fin (21A, 21B, 21C, 23A, 23B, 23C) can be the same throughout the entirety of the semiconductor fin (21A, 21B, 21C, 23A, 23B, 23C).

In a non-limiting illustrative embodiment, the first semiconductor fin 21A, the second semiconductor fin 21B, the fourth semiconductor fin 23A, and the fifth semiconductor fin 23B can include single crystalline silicon as the semiconductor material. The third semiconductor fin 21C can include one of a single crystalline silicon-germanium alloy or a silicon carbon alloy as the semiconductor material. The sixth semiconductor fin 23C can include another of a single crystalline silicon-germanium alloy or a silicon carbon alloy as the semiconductor material.

The width of each semiconductor fin (21A, 21B, 21C, 23A, 23B, 23C) can be in a range from 5 nm to 300 nm, although lesser and greater thicknesses can also be employed. The height of each semiconductor fin (21A, 21B, 21C, 23A, 23B, 23C) can be in a range from 30 nm to 600 nm, although lesser and greater thicknesses can also be employed.

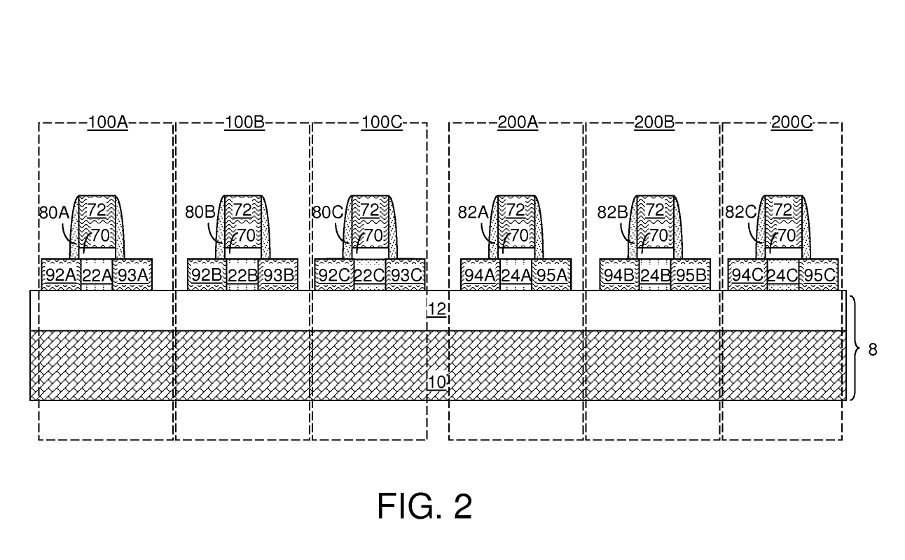

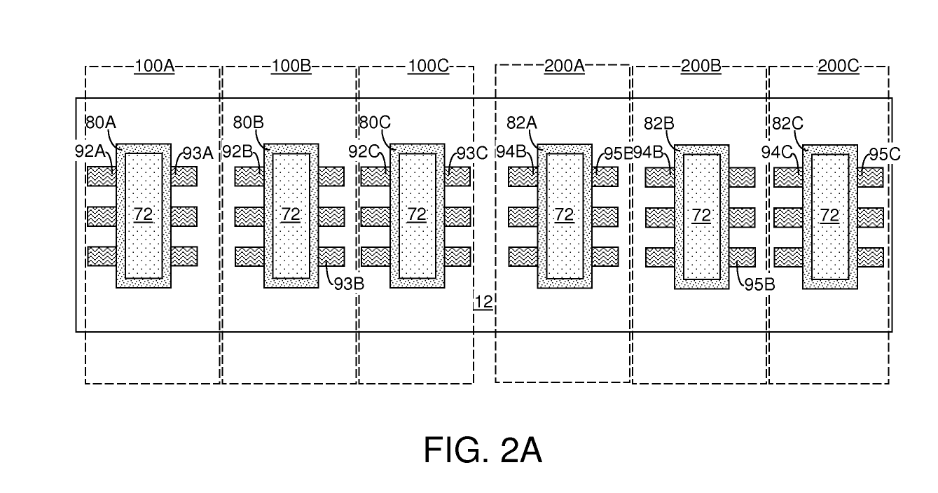

Referring to FIGS. 2 and 2A, a disposable dielectric layer and a disposable gate material layer are deposited and lithographically patterned to form disposable gate structures. In one embodiment, at least one disposable gate structure can be formed in each device region (100A, 100B, 100C, 200A, 200B, 200C). Each disposable gate stack can include a vertical stack of a disposable dielectric portion 70 and a disposable gate material portion 72. Each disposable dielectric portion 70 is a remaining portion of the disposable dielectric layer after the lithographic patterning, and each disposable gate material portion 72 is a remaining portion of the disposable gate material layer after the lithographic patterning. The disposable dielectric portions 70 can include a dielectric material such as silicon oxide, silicon nitride, and/or silicon oxynitride. The disposable gate material portions 72 can include a conductive material, semiconductor material, and/or a dielectric material that is different from the material of the disposable dielectric portions 70. The conductive material can be an elemental metal or a metallic compound, the semiconductor material can be silicon, germanium, a III-V compound semiconductor material, or an alloy or a stack thereof, and the dielectric material can be silicon oxide, silicon nitride, or porous or non-porous organosilicate glass (OSG).

Dielectric gate spacers can be formed on sidewalls of each of the disposable gate structures (70, 72), for example, by deposition of a conformal dielectric material layer and an anisotropic etch. The dielectric gate spacers can include, for example, a first gate spacer 80A formed in the first device region 100A, a second gate spacer 80B formed in the second device region 100B, a third gate spacer 80C formed in the third device region 100C, a fourth gate spacer 80A formed in the fourth device region 200A, a fifth gate spacer 80B formed in the fifth device region 200B, and a sixth gate spacer 80C formed in the sixth device region 200C.

Electrical dopants of a conductivity type can be implanted into the first, second, and third device regions (100A, 100B, 100C) to form various source and drain regions, which can include, for example, a first source region 92A, a first drain region 93A, a second source region 92B, a second drain region 93B, a third source region 92C, and a third drain region 93C. If any of the first, second, and third semiconductor fins (21A, 21B, 21C) is doped with dopants of a first conductivity type (which is p-type or n-type), the conductivity type of the implanted electrical dopants is a second conductivity type that is the opposite of the first conductivity type. For example, if the first conductivity type is p-type, the second conductivity type is n-type, and vice versa.

Further, electrical dopants of another conductivity type can be implanted into the first, second, and sixth device regions (200A, 200B, 200C) to form various source and drain regions, which can include, for example, a fourth source region 94A, a fourth drain region 95A, a fifth source region 94B, a fifth drain region 95B, a sixth source region 94C, and a sixth drain region 95C. If any of the first, second, and sixth semiconductor fins (23A, 23B, 23C) is doped with dopants of the second conductivity type (which is n-type or p-type), the conductivity type of the implanted electrical dopants is the first conductivity type.

The formation of the various source regions and the various drain regions can be performed prior to, and/or after, formation of the various gate spacers (80A, 80B, 80C, 82A, 82B, 82C). The remaining portions of the first, second, and third semiconductor fins (21A, 21B, 21C) constitute a first channel region 22A, a second channel region 22B, and a third channel region 22C, respectively. The remaining portions of the first, second, and sixth semiconductor fins (23A, 23B, 23C) constitute a fourth channel region 24A, a fifth channel region 24B, and a sixth channel region 24C, respectively. Each of the channel regions (22A, 22B, 22C, 24A, 24B, 24C) can include an intrinsic semiconductor material or a doped semiconductor material.

Optionally, metal semiconductor alloy portions (not shown) can be formed on the physically exposed top surface of the various source regions (92A, 92B, 92C, 94A, 94B, 94C) and the various drain regions (93A, 93B, 93C, 95A, 95B, 95C), for example, by deposition of a metal layer and an anneal that forms a metal semiconductor alloy (such as a metal silicide). Unreacted remaining portions of the metal semiconductor alloy can be removed, for example, by a wet etch.

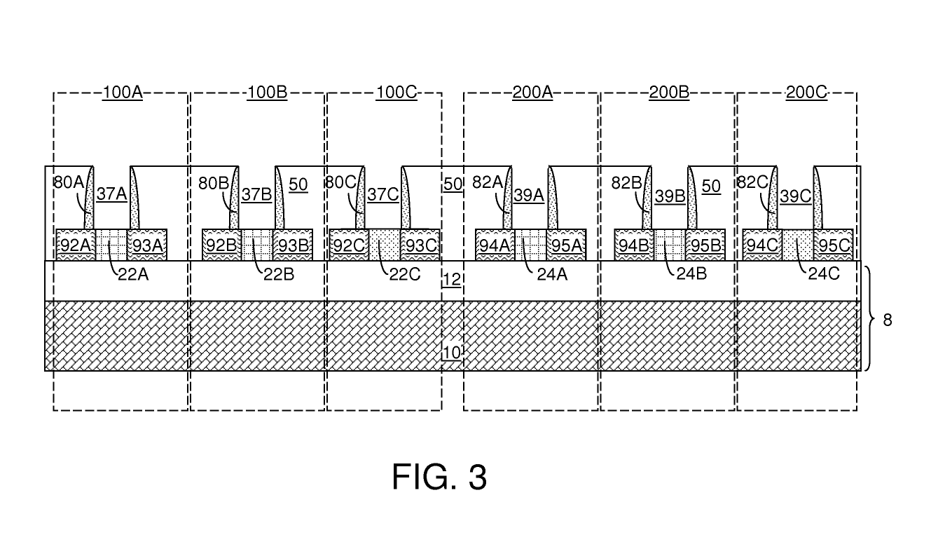

Referring to FIG. 3, a planarization dielectric layer 50 is deposited over the disposable gate structures (70, 72), the various gate spacers (80A, 80B, 80C, 82A, 82B, 82C), the various source regions (92A, 92B, 92C, 94A, 94B, 94C), and the various drain regions (93A, 93B, 93C, 95A, 95B, 95C). The planarization dielectric layer 50 includes a dielectric material, which can be a self-planarizing dielectric material such as a spin-on glass (SOG), or a non-planarizing dielectric material such as silicon oxide, silicon nitride, organosilicate glass, or combinations thereof. The planarization dielectric layer 50 is subsequently planarized, for example, by chemical mechanical planarization (CMP) such that top surfaces of the disposable gate structures (70, 72) become physically exposed. In one embodiment, the planarized top surface of the planarization dielectric layer 50 can be coplanar with the top surfaces of the disposable gate structures (70, 72).

Subsequently, the disposable gate stacks (70, 72) are removed selective to the planarization dielectric layer 50 and the various gate spacers (80A, 80B, 80C, 82A, 82B, 82C). The removal of the disposable gate stacks (70, 72) can be performed, for example, by an isotropic etch such as a wet etch, or by an anisotropic etch such as a reactive ion etch. Gate cavities are formed in spaces from which the disposable gate stacks (70, 72) are removed. The gate cavities can include, for example, a first gate cavity 37A that is formed in the first device region 100A, a second gate cavity 37B that is formed in the second device region 100B, a third gate cavity 37C that is formed in the third device region 100C, a fourth gate cavity 39A that is formed in the fourth device region 200A, a fifth gate cavity 39B that is formed in the fifth device region 200B, and a sixth gate cavity 39C that is formed in the sixth device region 200C. A semiconductor surface of an intrinsic semiconductor material is physically exposed at the bottom of each gate cavity (37A, 37B, 37C, 39A, 39B, 39C).

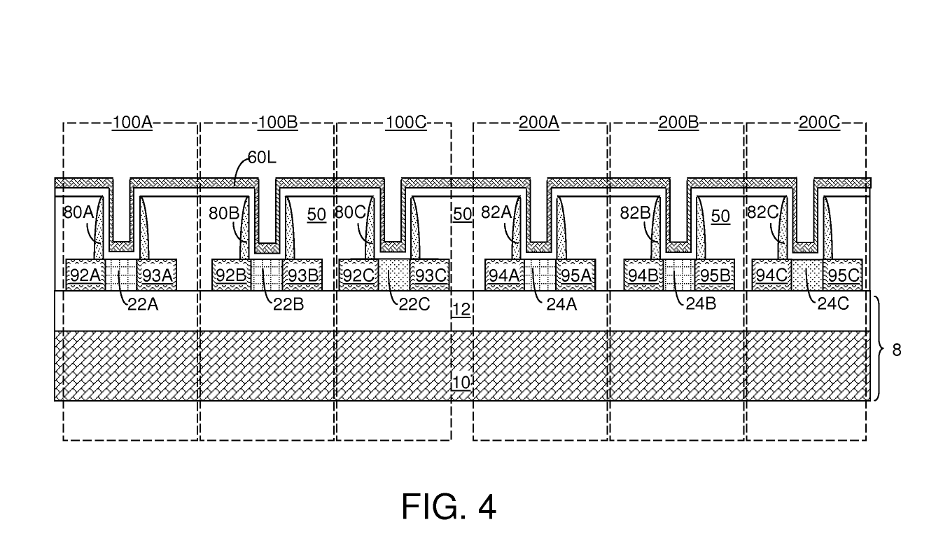

Referring to FIG. 4, a high dielectric constant (high-k) dielectric layer 30L is formed on the bottom surfaces and sidewall surfaces of the gate cavities (37A, 37B, 37C, 39A, 39B, 39C) and on the top surface of the planarization dielectric layer 50. The high-k dielectric layer 30L contacts inner sidewall surfaces of the gate spacers (80A, 80B, 80C, 82A, 82B, 82C). Optionally, a dielectric interface layer (not shown) may be formed directly on the top surfaces of the channel regions (22A, 22B, 22C, 24A, 24B, 24C) before deposition of the high-k dielectric layer 30L. The dielectric interface layer may include a semiconductor oxide, a semiconductor oxynitride, or a semiconductor nitride. For example, the dielectric interface layer may be a “chemical oxide,” which is formed by treatment of top surfaces of the channel regions (22A, 22B, 22C, 24A, 24B, 24C) with a chemical. The thickness of the dielectric interface layer, if present, may be from 0.1 nm to 0.8 nm, although lesser and greater thicknesses are also contemplated herein. Otherwise, the high-k dielectric material layer 30L may be formed directly on the channel regions (22A, 22B, 22C, 24A, 24B, 24C).

The high dielectric constant (high-k) dielectric layer 30L can be formed on the channel regions (22A, 22B, 22C, 24A, 24B, 24C) employing, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The high-k dielectric layer 30L can include a high dielectric constant (high-k) dielectric material. As used herein, a “high-k dielectric material” refers to a dielectric material having a dielectric constant greater than the dielectric constant of silicon oxide, which is 3.9. The high-k dielectric layer 30L can have a dielectric constant greater than 4.0. In one embodiment, the high-k dielectric material can be a dielectric metal oxide having a dielectric constant that is greater than the dielectric constant of silicon nitride, which is 7.9. In one embodiment, the high-k dielectric layer 30L has a dielectric constant greater than 8.0. In one embodiment, the high-k dielectric layer 30L can consist essentially of a dielectric metal oxide having a dielectric constant greater than 8.0. The dielectric material of the high-k dielectric layer 30L is herein referred to as a first high-k dielectric material. In one embodiment, the first high-k dielectric material can include a material selected from hafnium oxide, zirconium oxide, tantalum oxide, titanium oxide, silicates of thereof, and alloys thereof. In one embodiment, the first high-k dielectric material can consist essentially of a material selected from hafnium oxide, zirconium oxide, tantalum oxide, titanium oxide, silicates of thereof, and alloys thereof. The thickness of the high-k dielectric layer 30L may be from 0.9 nm to 6 nm, and preferably from 1.2 nm to 3 nm. The high-k dielectric layer 30L may have an effective oxide thickness on the order of or less than 1 nm.

A diffusion barrier metallic nitride layer 60L is formed directly on the high-k dielectric layer 30L. The diffusion barrier metallic nitride layer 60L contains a metallic nitride material that functions as a diffusion barrier for metals. The diffusion barrier metallic nitride layer 60L may contain, for example, TiN, TaN, WN, or a combination thereof. The diffusion barrier metallic nitride layer 60L may be formed by chemical vapor deposition (CVD), physical vapor deposition (PVD), atomic layer deposition (ALD), vacuum evaporation, etc. The thickness of the diffusion barrier metallic nitride layer 60L may be from 3 nm to 30 nm, and typically from 5 nm 20 nm, although lesser and greater thicknesses are also contemplated herein.

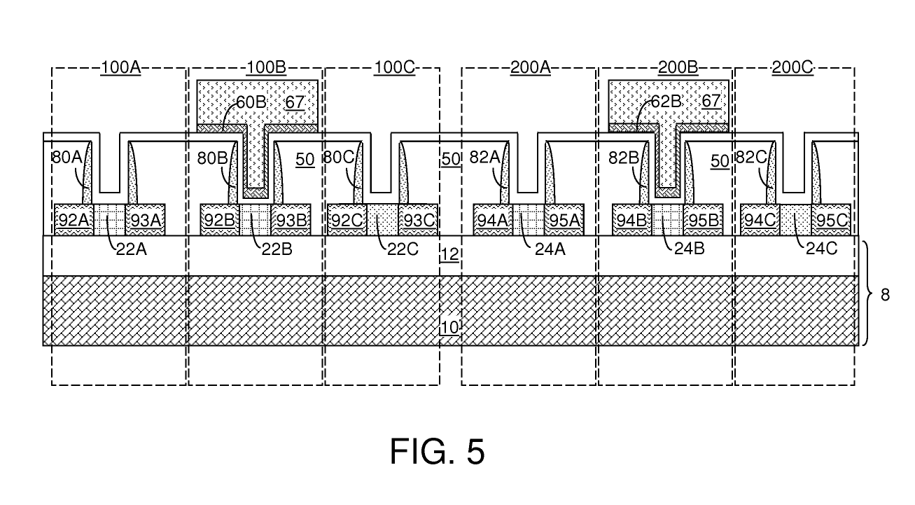

Referring to FIG. 5, a photoresist layer 67 is applied over the diffusion barrier metallic nitride layer 60L, and is lithographically patterned by lithographic exposure and development. The photoresist layer 67 is patterned to cover at least one gate cavity, while physically covering at least another gate cavity. The diffusion barrier metallic nitride layer 60L is then patterned by an etch process that employs the patterned photoresist layer 67 as an etch mask. Upon patterning of the diffusion barrier metallic nitride layer 60L, at least one portion of the high-k dielectric layer 30L is physically exposed while at least another portion of the high-k dielectric layer 30L is covered by a patterned portion of the diffusion barrier metallic nitride layer 30L.

In a non-limiting illustrative example, a first patterned portion of the diffusion barrier metallic nitride layer 30L can be present in the second device region 100B, and a second patterned portion of the diffusion barrier metallic nitride layer 30L can be present in the fifth device region 200B. The first patterned portion of the diffusion barrier metallic nitride layer 30L is herein referred to as a first-type diffusion barrier metallic nitride portion 60B, and the second patterned portion of the diffusion barrier metallic nitride layer 30L is herein referred to as a second-type diffusion barrier metallic nitride portion 62B. The first-type diffusion barrier metallic nitride portion 60B overlies the entirety of the gate cavity in the second device region 100B, and the second-type diffusion barrier metallic nitride portion 62B overlies the entirety of the gate cavity in the fifth device region 200B. While the present disclosure is described employing an embodiment in which patterned portions of the diffusion barrier metallic nitride layer 30L overlie gate cavities in the second device region 100B and the fifth device region 200B, embodiments are expressly contemplated herein in which patterned portions of the diffusion barrier metallic nitride layer 30L independently overlie any of the gate cavities in the various device regions (100A, 100B, 100C, 200A, 200B, 200C). The patterned photoresist layer 67 is subsequently removed, for example, by ashing.

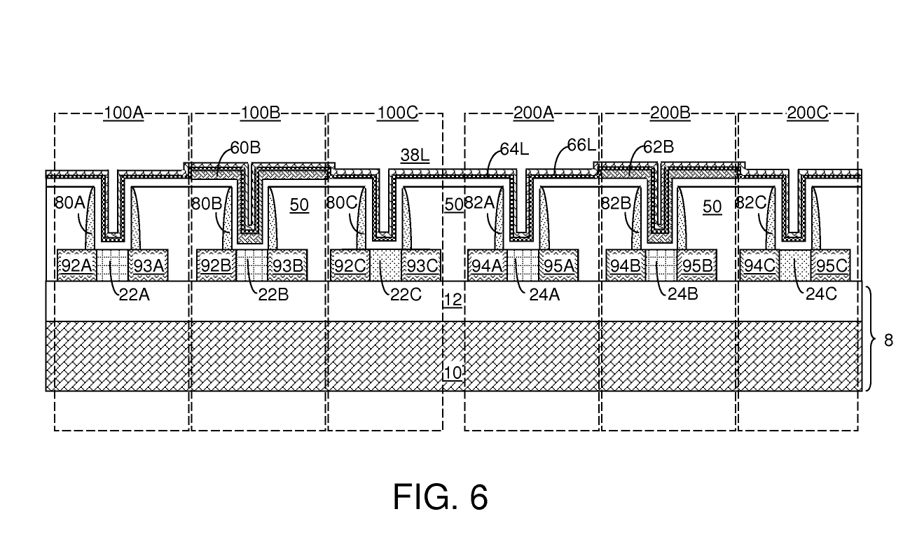

Referring to FIG. 6, a threshold voltage adjustment oxide layer 64L is deposited directly on the diffusion barrier metallic nitride portions (60B, 62B) and the high-k dielectric layer 30L. The threshold voltage adjustment oxide layer 64L includes a dielectric metal oxide having a dielectric constant that is greater than the dielectric constant of silicon oxide of 3.9. The threshold voltage adjustment oxide layer 64L can have dielectric constant greater than 4.0. In one embodiment, the threshold voltage adjustment oxide layer 64L has a dielectric constant greater than 8.0.

The dielectric material of the threshold voltage adjustment oxide layer 64L is herein referred to as a second high-k dielectric material. The second high-k dielectric material has a different composition than the first high-k dielectric material. In one embodiment, the second high-k dielectric material can include a material selected from an oxide of a Group IIA element, an oxide of a Group MB element, aluminum oxide (Al₂O₃), and alloys thereof. As such, the second high-k material of the threshold voltage adjustment oxide layer 64L alters the threshold voltage of a fin field effect transistor if the second high-k material contacts the channel of the fin field effect transistor or is placed in proximity with the channel at a distance less than about 2 nm.

The threshold voltage adjustment oxide layer 64L can be formed employing, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. The thickness of the threshold voltage adjustment oxide layer 64L may be from 0.9 nm to 6 nm, and preferably from 1.2 nm to 3 nm. The threshold voltage adjustment oxide layer 64L may have an effective oxide thickness on the order of or less than 1 nm.

Optionally, a cap material layer 66L can be deposited over the threshold voltage adjustment oxide layer 64L. If a cap material layer 66L is employed, a portion of the cap material layer 66L is deposited directly on the threshold voltage adjustment oxide layer 64L. The cap material layer 66L includes at least one of a metallic material layer and a semiconductor material layer. In one embodiment, the cap material layer 66L includes a metallic nitride layer such as a TiN layer, a TaN layer, or a WN layer. In another embodiment, the cap material layer 66L includes an amorphous or polycrystalline semiconductor material layer including silicon, a silicon-germanium alloy, or a silicon-carbon alloy. In one embodiment, the cap material layer 66L can include a vertical stack, from bottom to top, of a metallic nitride layer and an amorphous or polycrystalline semiconductor material layer. The cap material layer 66L can be deposited, for example, by physical vapor deposition (PVD), chemical vapor deposition (CVD), atomic layer deposition (ALD), or a combination thereof. The cap material layer 66L can have a thickness in a range from 2 nm to 100 nm, although lesser and greater thicknesses can also be employed.

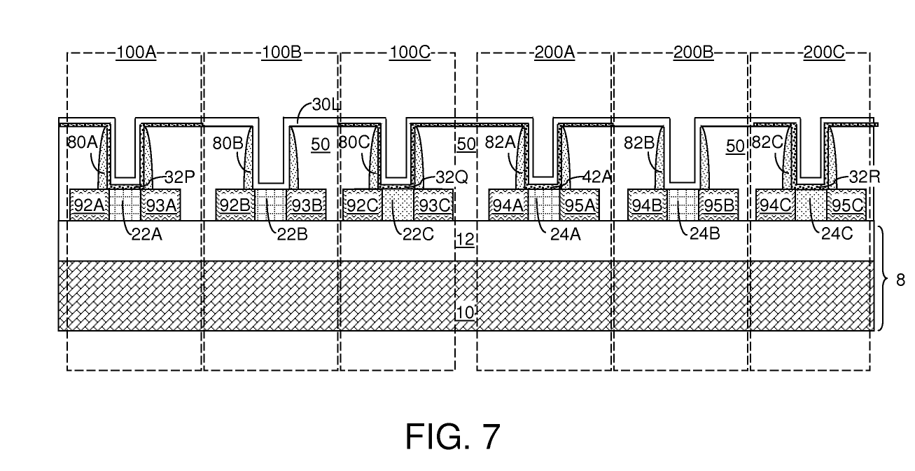

Referring to FIG. 7, the first exemplary semiconductor structure is annealed at an elevated temperature. The elevated temperature can be, for example, in a range from 500° C. to 900° C., although lower and higher temperatures can also be employed. The anneal induces diffusion of the second high-k dielectric material through the first high-k dielectric material by an anneal. During the anneal, the diffusion barrier metallic nitride portions (60B, 62B), i.e., the patterned diffusion barrier metallic nitride layer, blocks diffusion of the second high-k dielectric material therethrough. The first high-k dielectric material diffuses through the second high-k dielectric material during the anneal, and accumulates at the interface with the channel regions (22A, 22C, 24A, 24C), the gate spacers (80A, 80C, 82A, 82C), and the top surface of the planarization dielectric layer 50 that are present within the device regions (100A, 100C, 200A, 200C) in which the patterned diffusion barrier metallic nitride layer does not block the diffusion of the first high-k dielectric material. Thus, each threshold voltage adjustment oxide portion (32P, 32Q, 32R) is formed in (a) device region(s) in which the patterned diffusion barrier metallic nitride layer does not block the diffusion of the first high-k dielectric material. The threshold voltage adjustment oxide portions (32P, 32Q, 32R) are formed directly on at least one of the plurality of semiconductor material regions, and specifically, directly on the channel regions (22A, 22C, 24A, 24C). In one embodiment, the concentration of the second high-k dielectric material can be the greatest at the interface with underlying channel regions (22A, 22C, 24A, 24C).

The optional cap material layer 66L, the remaining portions of the threshold voltage adjustment oxide layer 64L overlying the diffusion barrier metallic nitride portions (60B, 62B), and the diffusion barrier metallic nitride portions (60B, 62B) are subsequently removed selective to the high-k dielectric layer 30L, i.e., without removing the high-k dielectric layer 30L. The selective removal of the optional cap material layer 66L, the remaining portions of the threshold voltage adjustment oxide layer 64L, and the diffusion barrier metallic nitride portions (60B, 62B) can be effected, for example, by a wet etch. In one embodiment, remaining portions of the threshold voltage adjustment oxide layer 64L after diffusion of the second high-k dielectric material through the high-k dielectric layer 30L can be removed selective to the first high-k dielectric material of the high-k dielectric layer, for example, by a wet etch.

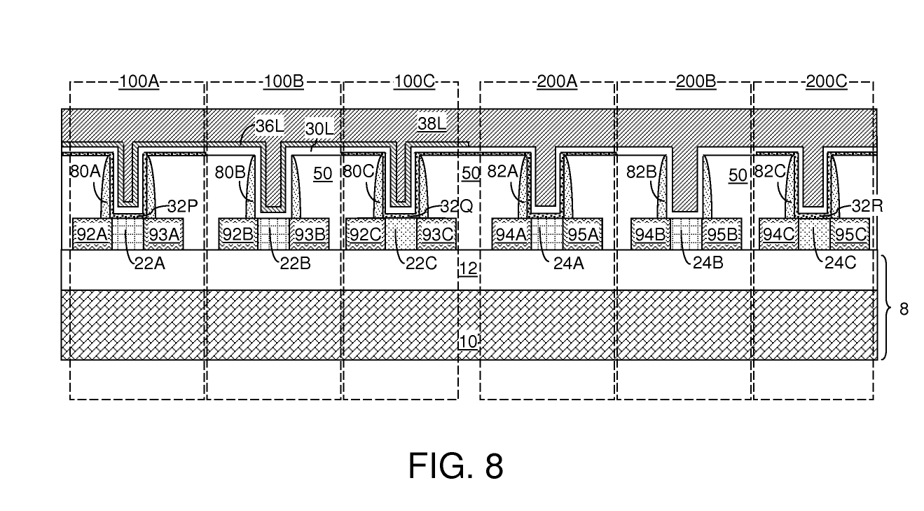

Referring to FIG. 8, at least one conductive material layer is deposited within the various gate trenches. In one embodiment, the at least one conductive material layer can include at least one work function material layer. In an illustrative example, a first work function material layer 36L can be deposited on the high-k dielectric layer 30L. The material of the first work function material layer 36L has a first work function, and can be selected from any work function material known in the art. The first work function material layer 36L can include an elemental only, or can include a metallic compound, which includes a metal and a non-metal element. The metallic compound is selected to optimize the performance of fin field effect transistor to be subsequently formed in the device regions in which first-type channel regions (22A, 22B, 22C) are present. The metallic compound can be selected from tantalum carbide, metallic nitrides, and a hafnium-silicon alloy. Exemplary metallic nitrides include titanium nitride, tantalum nitride, tungsten nitride, and combinations and alloys thereof.

The first work function material layer 36L can be formed, for example, by physical vapor deposition, chemical vapor deposition, or atomic layer deposition (ALD). The thickness of the first work function material layer 36L is typically set at a value from 1 nm to 30 nm, and more typically, from 2 nm to 10 nm, although lesser and greater thicknesses can also be employed.

A photoresist layer (not shown) is applied and lithographic patterned so that the photoresist layer covers the area over the device regions in which first-type channel regions (22A, 22B, 22C) are present, while the top surface of the first work function material layer 36L is exposed over the device regions in which second-type channel regions (24A, 24B, 24C) are present. The pattern in the photoresist layer is transferred into the first work function material layer 36L by an etch. The portion of the first work function material layer 36L in the device regions in which second-type channel regions (24A, 24B, 24C) are present is removed employing the photoresist layer as an etch mask. The photoresist layer is removed, for example, by ashing or wet etching. After the patterning of the first work function material layer 36L, a remaining portion of the first work function material layer 36L is present in the device regions in which first-type channel regions (22A, 22B, 22C) are present. The photoresist layer is subsequently removed, for example, by ashing.

A second work function material layer 38L can be subsequently deposited. The second work function material layer 38L includes a second metal having a second work function, which can be different from the first work function. The material of the second work function material layer 38L h can be selected from any work function material known in the art. The material of the second work function material layer 38L is selected to optimize the performance of the fin field effect transistor to be subsequently formed in the device regions in which second-type channel regions (24A, 24B, 24C) are present.

The second work function material layer 38L can be formed, for example, by physical vapor deposition, chemical vapor deposition, or atomic layer deposition (ALD). The thickness of the second work function material layer 38L is typically set at a value from 2 nm to 100 nm, and more typically, from 3 nm to 10 nm, although lesser and greater thicknesses can also be employed.

In one embodiment, the first work function material layer 36L can include a work function material optimized for forming p-type fin field effect transistors and the second work function material layer 38L can include another work function material optimized for forming n-type fin field effect transistors. Alternatively, the first work function material layer 36L can include a work function material optimized for forming n-type fin field effect transistors and the second work function material layer 38L can include another work function material optimized for forming p-type fin field effect transistors.

In one embodiment, an additional conductive material layer (not shown) can be deposited on the second work function material layer 38L. The additional conductive material layer can include, for example, a doped semiconductor material layer and/or a metallic material layer.

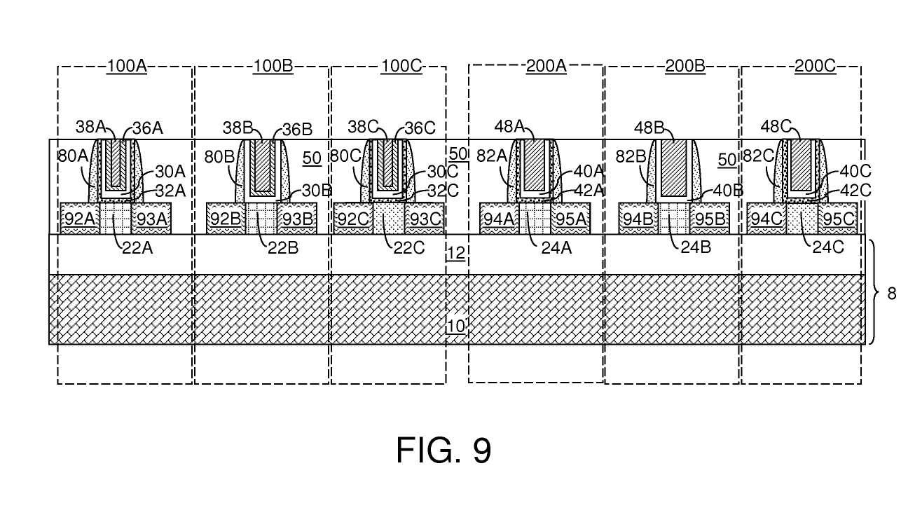

Referring to FIG. 9, gate stacks are formed by patterning the at least one conductive material layer (36L, 38L), the high-k dielectric layer 30L, and the at least one threshold voltage adjustment oxide portion (60B, 62B) by a planarization process. The planarization process can be a chemical mechanical planarization (CMP) process employing the planarization dielectric layer 50 as a stopping layer. In this case, the work function material layers (36L, 38L), the high-k dielectric layer 30L, and the at least one threshold voltage adjustment oxide portion (60B, 62B) from above the top surface of a planarization dielectric layer 50 by chemical mechanical planarization.

Remaining portions of the high-k dielectric layer 30L can include a first high-k dielectric layer 30A in the first device region 100A, a second high-k dielectric layer 30B in the second device region 100B, a third high-k dielectric layer 30C in the third device region 100C, a fourth high-k dielectric layer 40A in the fourth device region 200A, a fifth high-k dielectric layer 40B in the fifth device region 200B, and a sixth high-k dielectric layer 40C in the sixth device region 200C. Remaining portions of the threshold voltage adjustment oxide portion (32P, 32Q, 32R) can include a first threshold voltage adjustment oxide portion 32A in the first device region 100A, a second threshold voltage adjustment oxide portion 32C in the third device region 100C, a fourth threshold voltage adjustment oxide portion 42A in the fourth device region 200A, and a fifth threshold voltage adjustment oxide portion 42C in the sixth device region 200C. Remaining portions of the first work function material layer 36L can include a first first-work-function-material portion 36A, a second first-work-function-material portion 36B, and a third first-work-function-material portion 36C. Remaining portions of the second work function material layer 38L can include a first second-work-function-material portion 38A, a second second-work-function-material portion 38B, a third second-work-function-material portion 38C, a fourth second-work-function-material portion 48A, a fifth second-work-function-material portion 48B, and a sixth second-work-function-material portion 48C.

The first exemplary semiconductor structure can include a first fin field effect transistor including a first gate stack. The first gate stack can include, from bottom to top, a first high dielectric constant (high-k) dielectric portion (such as the second dielectric portion 30B) including the first high-k dielectric material having a dielectric constant greater than 4.0 and straddling a first semiconductor fin (such as the second semiconductor fin (22B, 92B, 93B) and contacting a first channel region (such as the second channel region 22B), and a first gate electrode (such as the stack of the second first-work-function-material portion 36B and the second second-work-function-material portion 38B) contacting the first high-k dielectric portion.

The first exemplary semiconductor structure can further include a second fin field effect transistor including a second gate stack. The second gate stack includes, from bottom to top, a threshold voltage adjustment oxide portion (such as the first threshold voltage adjustment oxide portion 32A) including the second high-k dielectric material having a second high-k dielectric constant greater than 4.0 and different from the first high-k dielectric material and straddling a second semiconductor fin (such as the first semiconductor fin (22A, 92A, 93A) and contacting a second channel region (such as the first channel region 22A), a second high-k dielectric portion (such as the first high-k dielectric layer 30A) including the first high-k dielectric material, and a second gate electrode (such as the stack of the first first-work-function-material portion 36A and the first second-work-function-material portion 38A) contacting the second high-k dielectric portion.

The first exemplary semiconductor structure can further include at least one second-type fin field effect transistor including another gate stack. The gate stack can include at least, from bottom to top, a high-k dielectric portion including the first high-k dielectric material and a gate electrode contacting the third high-k dielectric portion.

The at least one second-type fin field effect transistor can include a fourth fin field effect transistor including a third gate stack. The third gate stack can includes at least, from bottom to top, a threshold voltage adjustment oxide portion (such as the fourth threshold voltage adjustment oxide portion 42A) including the second high-k dielectric material and straddling a third semiconductor fin (such as the fourth semiconductor fin (24A, 94A, 95A) and contacting a third channel region (such as the fourth channel region 24A), a third high-k dielectric portion (such as the fourth high-k dielectric layer 40A) including the first high-k dielectric material, and a third gate electrode (such as the fourth second-work-function-material portion 48A) contacting the third high-k dielectric portion.

The at least one second-type fin field effect transistor can include a fifth fin field effect transistor including a fourth gate stack. The fourth gate stack can include, from bottom to top, a threshold voltage adjustment oxide portion (such as the sixth threshold voltage adjustment oxide portion 42C) including the second high-k dielectric material and straddling a fourth semiconductor fin (such as the fifth semiconductor fin (24B, 94B, 95B) and contacting a fourth channel region (such as the sixth channel region 24C), a fourth high-k dielectric portion (such as the sixth channel region 24C) including the first high-k dielectric material, and a fourth gate electrode (such as the sixth second-work-function-material portion 48C) contacting the fourth high-k dielectric portion. The third channel region and the fourth channel region can be single crystalline intrinsic semiconductor material portions including different semiconductor materials.

Alternatively or additionally, the at least one second fin field effect transistor can include another fin field effect transistor including a gate stack. The gate stack can include a high-k dielectric portion (such as the fifth high-k dielectric layer 40B) including the first high-k dielectric material and straddling a semiconductor fin (such as the fifth semiconductor fin (24B, 94B, 95B) and contacting a channel region (such as the fifth channel region 24B) and a gate electrode (such as the fifth second-work-function-material portion 48C) contacting the high-k dielectric portion.

In one embodiment, the atomic concentration of the second high-k dielectric material can decrease with distance from the interface between the underlying channel region (22A, 22C, 24A, 24C) and the underlying threshold voltage adjustment oxide portion (32A, 32C, 42A, 42C) within a high-k dielectric layer (30A, 30C, 40A, 40C) including the first high-k dielectric material and the diffused second high-k dielectric material. A predominant portion, i.e., more than 50% in atomic concentration, of each high-k dielectric layer (30A, 30C, 40A, 40C) can be the first high-k dielectric material, and the balance can be the second high-k dielectric material.

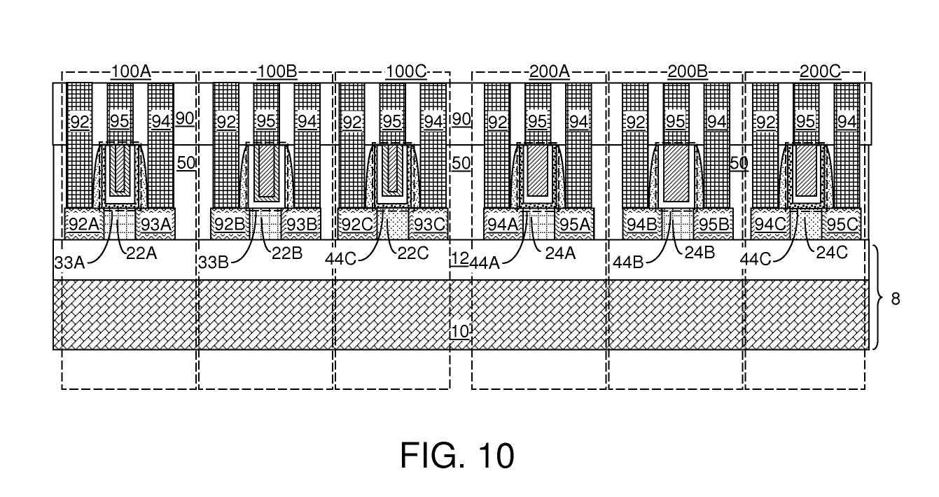

Referring to FIG. 10, a contact level dielectric layer 90 can be deposited over the planarization dielectric layer 50, for example, by chemical vapor deposition (CVD) or spin-coating. The contact level dielectric layer 90 includes a dielectric material such as silicon oxide, silicon nitride, and/or organosilicate glass. Various contact via structures can be formed through the contact level dielectric layer 90 and the planarization dielectric layer 50. The various contact via structures can include, for example, source-side contact via structures 92, drain-side contact via structures 94, and gate-side contact via structures 95. A first gate stack 33A is present in the first device region 100A, a second gate stack 33B is present in the second device region 100B, a third gate stack 33C is present in the third device region 100C, a fourth gate stack 33A is present in the fourth device region 200A, a fifth gate stack 33B is present in the fifth device region 200B, and a sixth gate stack 33C is present in the sixth device region 200C.

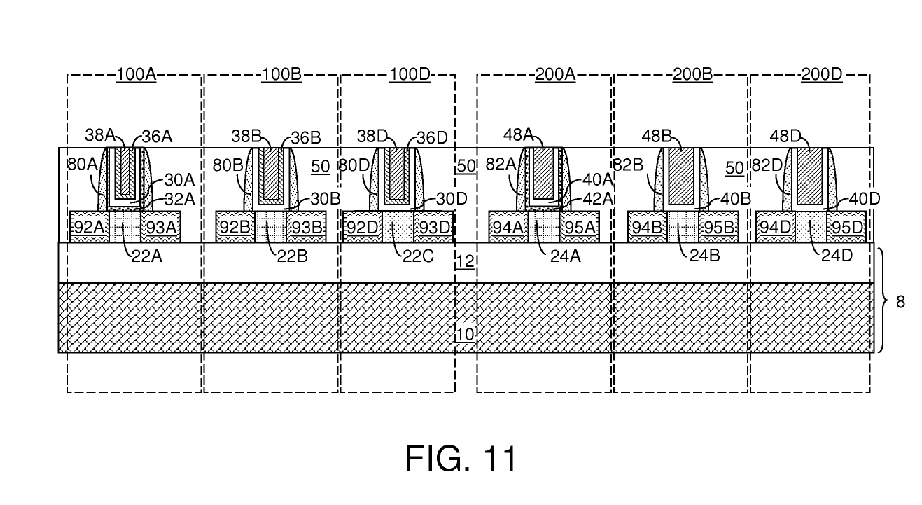

Referring to FIG. 11, a variation of the first exemplary semiconductor structure can be derived from the first exemplary semiconductor structure by adding a fourth first-type device region 100D and/or a fourth second-type device region 200D and by performing the processing steps of FIGS. 1-9. Alternatively, the fourth first-type device region 100D can substitute any of the first-type device regions (100A, 100B, 100C), and/or the fourth second-type device region 200D can substitute any of the second-type device regions (200A, 200B, 200C).

The fourth first-type device region 100D can include a fourth first-type channel region 22C having a same composition as a third channel region 22C (See FIG. 9). The fourth first-type device region 100D can further include a fourth first-type source region 92D having a same composition as a third source region 92C (See FIG. 9), and a fourth first-type drain region 93D having a same composition as a third drain region 93C (See FIG. 9). The fourth-type device region 100D can include a fourth first-type gate spacer 80D having a same composition and thickness as a third gate spacer 80C (See FIG. 9). The fourth first-type device region 100D can include a fourth first-type high-k gate dielectric layer 30D having a same composition as a second high-k gate dielectric layer 30B, a fourth first-work-function-material portion 36D having a same composition as a second first-work-function-material portion 36B, and a fourth first-type second-work-function-material portion 38D having a same composition as a second second-work-function-material portion 38B.

The fourth second-type device region 200D can include a fourth second-type channel region 24C having a same composition as a sixth channel region 24C (See FIG. 9). The fourth second-type device region 200D can further include a fourth second-type source region 94D having a same composition as a sixth source region 94C (See FIG. 9), and a fourth second-type drain region 95D having a same composition as a sixth drain region 95C (See FIG. 9). The fourth-type device region 200D can include a fourth second-type gate spacer 82D having a same composition and thickness as a sixth gate spacer 82C (See FIG. 9). The fourth second-type device region 200D can include a fourth second-type high-k gate dielectric layer 40D having a same composition as a fifth high-k gate dielectric layer 40B, a fourth first-work-function-material portion 36D having a same composition as a second first-work-function-material portion 36B, and a fourth second-type second-work-function-material portion 48D having a same composition as a fifth second-work-function-material portion 48B. The processing steps of FIG. 10 can be subsequently performed.

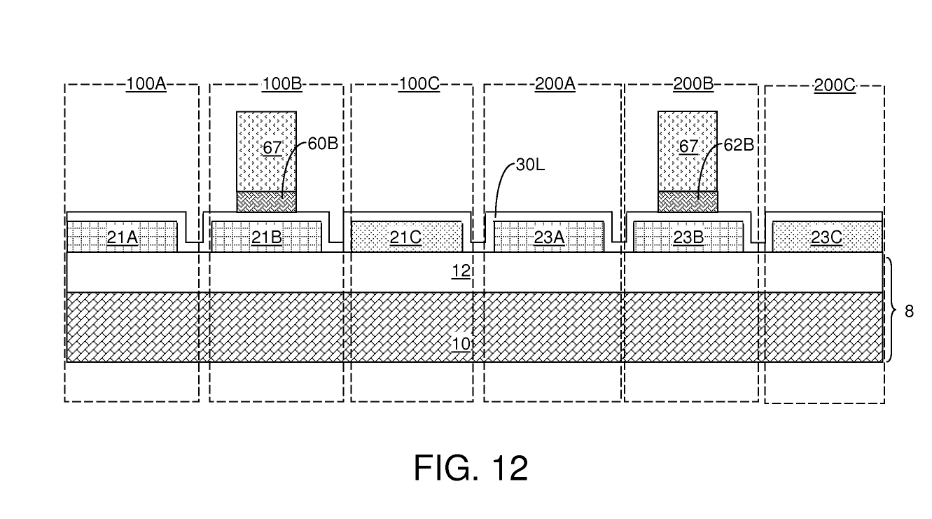

Referring to FIG. 12, a second exemplary semiconductor structure according to the second embodiment of the present disclosure can be derived from the first exemplary semiconductor structure of FIG. 1 by performing the processing steps of FIGS. 4 and 5 without performing the processing steps of FIGS. 2 and 3. In the second embodiment, the high-k dielectric layer 30L and the diffusion barrier metallic nitride layer 60L can be formed as blanket layers having the same thickness throughout. The diffusion barrier metallic nitride layer 60L is patterned to form various diffusion barrier metallic nitride portions (60B, 62B).

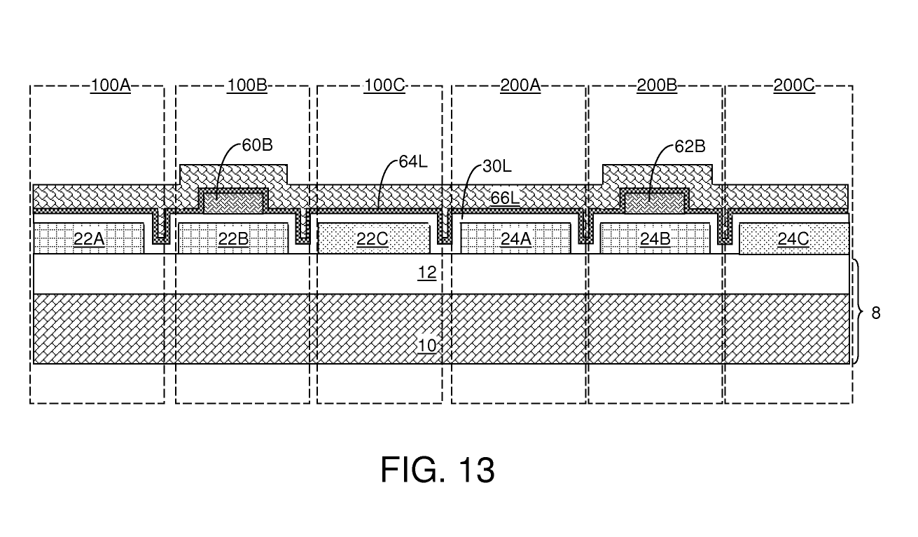

Referring to FIG. 13, a threshold voltage adjustment oxide layer 64L and an optional cap material layer 66L are deposited employing the processing steps of the first embodiment corresponding to FIG. 6.

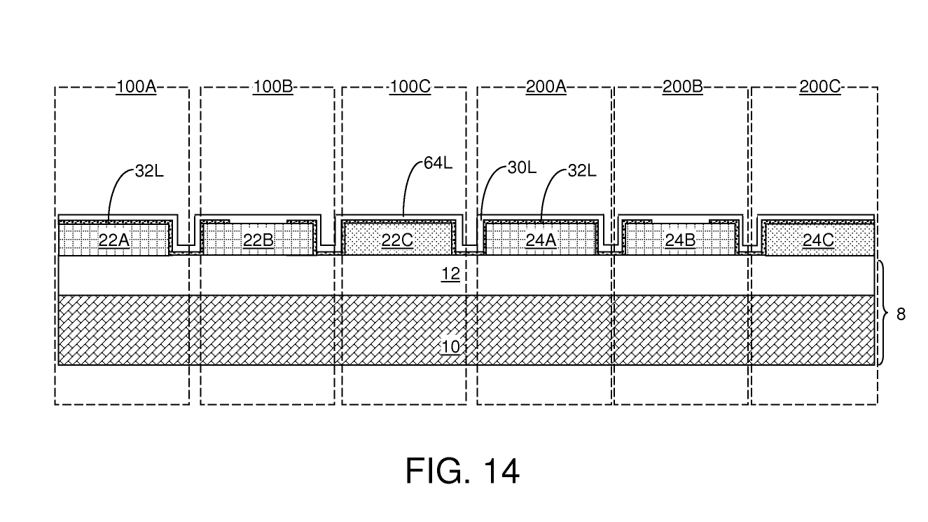

Referring to FIG. 14, an anneal is performed to form threshold voltage adjust oxide portions (32P, 32Q, 32R) between intrinsic semiconductor material regions (23A′, 23C′, 25A′, 25C′) and the high-k gate dielectric layer 30L employing the processing steps of the first embodiment corresponding to FIG. 7.

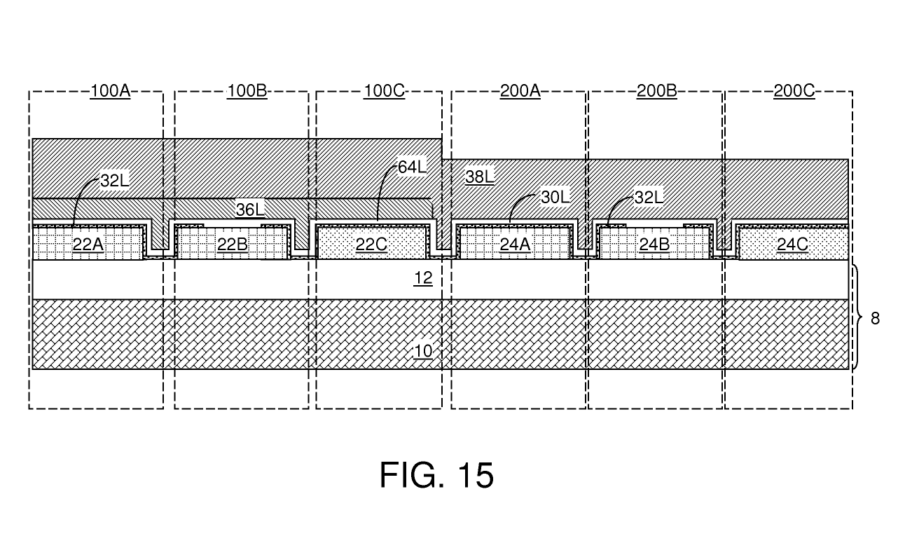

Referring to FIG. 15, at least one conductive material layer (36L, 38L) is deposited employing the processing steps of the first embodiment corresponding to FIG. 8.

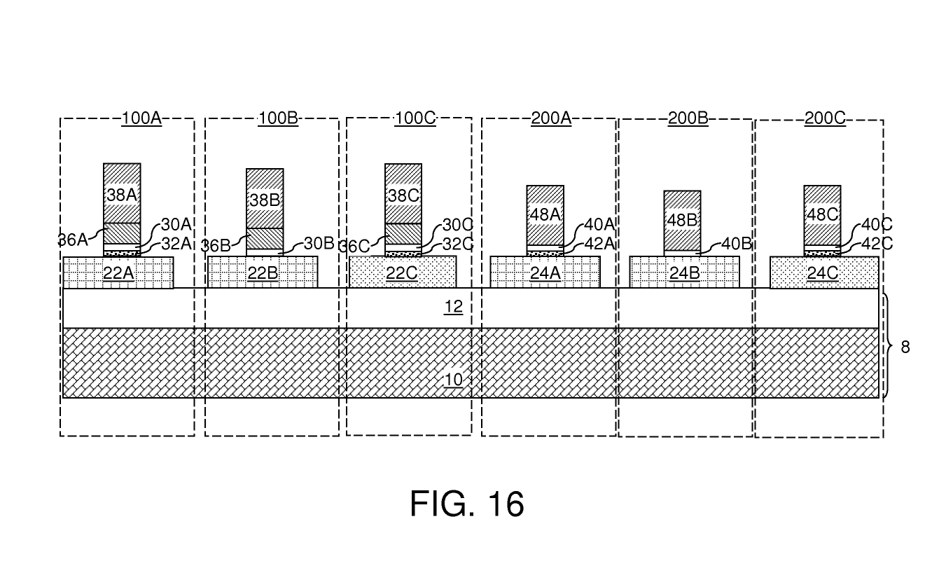

Referring to FIG. 16, various gate stacks are patterned by a combination of lithographic methods and at least one anisotropic etch. For example, a photoresist layer (not shown) can be applied over the at least one conductive material layer (36L, 38L) and patterned by lithographic exposure and development, and the pattern in the photoresist layer can be transferred through the at least one conductive material layer (36L, 38L), the high-k dielectric layer 30L, and the threshold voltage adjust oxide portions (32P, 32Q, 32R).

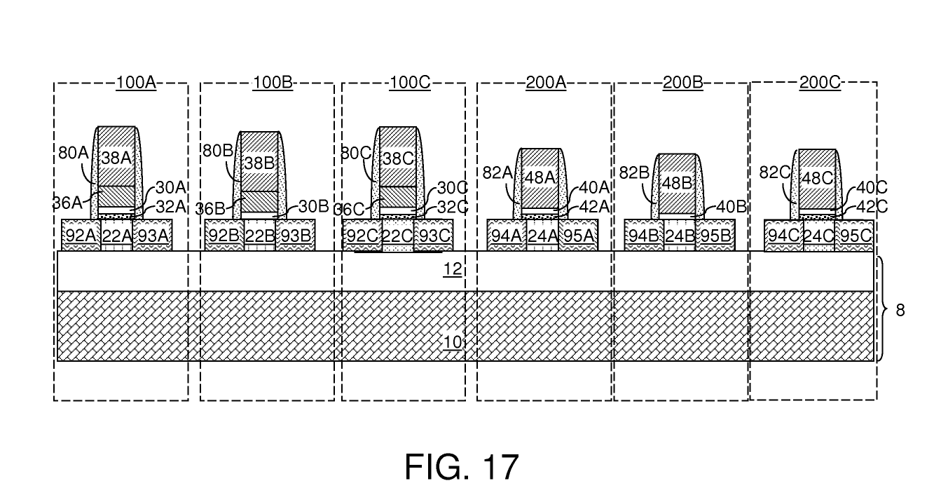

Referring to FIG. 17, gate spacers (80A, 30B, 30C, 82A, 82B, 82C), source regions (92A, 92B, 92C, 94A, 94B, 94C), and drain regions (93A, 93B, 93C, 95A, 95B, 95C) are formed employing the processing steps of the first embodiment corresponding to FIG. 2.

Remaining portions of the high-k dielectric layer 30L can include a first high-k dielectric layer 30A in the first device region 100A, a second high-k dielectric layer 30B in the second device region 100B, a third high-k dielectric layer 30C in the third device region 100C, a fourth high-k dielectric layer 40A in the fourth device region 200A, a fifth high-k dielectric layer 40B in the fifth device region 200B, and a sixth high-k dielectric layer 40C in the sixth device region 200C. Remaining portions of the threshold voltage adjustment oxide portion (32P, 32Q, 32R) can include a first threshold voltage adjustment oxide portion 32A in the first device region 100A, a second threshold voltage adjustment oxide portion 32C in the third device region 100C, a fourth threshold voltage adjustment oxide portion 42A in the fourth device region 200A, and a fifth threshold voltage adjustment oxide portion 42C in the sixth device region 200C. Remaining portions of the first work function material layer 36L can include a first first-work-function-material portion 36A, a second first-work-function-material portion 36B, and a third first-work-function-material portion 36C. Remaining portions of the second work function material layer 38L can include a first second-work-function-material portion 38A, a second second-work-function-material portion 38B, a third second-work-function-material portion 38C, a fourth second-work-function-material portion 48A, a fifth second-work-function-material portion 48B, and a sixth second-work-function-material portion 48C.

The second exemplary semiconductor structure can include a first fin field effect transistor including a first gate stack. The first gate stack can include, from bottom to top, a first high dielectric constant (high-k) dielectric portion (such as the second dielectric portion 30B) including the first high-k dielectric material having a dielectric constant greater than 4.0 and contacting a first channel region (such as the second channel region 22B), and a first gate electrode (such as the stack of the second first-work-function-material portion 36B and the second second-work-function-material portion 38B) contacting the first high-k dielectric portion.

The second exemplary semiconductor structure can further include a second fin field effect transistor including a second gate stack. The second gate stack includes, from bottom to top, a threshold voltage adjustment oxide portion (such as the first threshold voltage adjustment oxide portion 32A) including the second high-k dielectric material having a second high-k dielectric constant greater than 4.0 and different from the first high-k dielectric material and contacting a second channel region (such as the first channel region 22A), a second high-k dielectric portion (such as the first high-k dielectric layer 30A) including the first high-k dielectric material, and a second gate electrode (such as the stack of the first first-work-function-material portion 36A and the first second-work-function-material portion 38A) contacting the second high-k dielectric portion.

The second exemplary semiconductor structure can further include at least one second-type fin field effect transistor including another gate stack. The gate stack can include at least, from bottom to top, a high-k dielectric portion including the first high-k dielectric material and a gate electrode contacting the third high-k dielectric portion.

The at least one second-type fin field effect transistor can include a fourth fin field effect transistor including a third gate stack. The third gate stack can includes at least, from bottom to top, a threshold voltage adjustment oxide portion (such as the fourth threshold voltage adjustment oxide portion 42A) including the second high-k dielectric material and contacting a third channel region (such as the fourth channel region 24A), a third high-k dielectric portion (such as the fourth high-k dielectric layer 40A) including the first high-k dielectric material, and a third gate electrode (such as the fourth second-work-function-material portion 48A) contacting the third high-k dielectric portion.

The at least one second-type fin field effect transistor can include a fifth fin field effect transistor including a fourth gate stack. The fourth gate stack can include, from bottom to top, a threshold voltage adjustment oxide portion (such as the sixth threshold voltage adjustment oxide portion 42C) including the second high-k dielectric material and contacting a fourth channel region (such as the sixth channel region 24C), a fourth high-k dielectric portion (such as the sixth channel region 24C) including the first high-k dielectric material, and a fourth gate electrode (such as the sixth second-work-function-material portion 48C) contacting the fourth high-k dielectric portion. The third channel region and the fourth semiconductor channel portions can be single crystalline intrinsic semiconductor material portions including different semiconductor materials.

Alternatively or additionally, the at least one second fin field effect transistor can include another fin field effect transistor including a gate stack. The gate stack can include a high-k dielectric portion (such as the fifth high-k dielectric layer 40B) including the first high-k dielectric material and contacting a channel region (such as the fifth channel region 24B) and a gate electrode (such as the fifth second-work-function-material portion 48C) contacting the high-k dielectric portion.

In one embodiment, the atomic concentration of the second high-k dielectric material can decrease with distance from the interface between the underlying channel region (22A, 22C, 24A, 24C) and the underlying threshold voltage adjustment oxide portion (32A, 32C, 42A, 42C) within a high-k dielectric layer (30A, 30C, 40A, 40C) including the first high-k dielectric material and the diffused second high-k dielectric material.

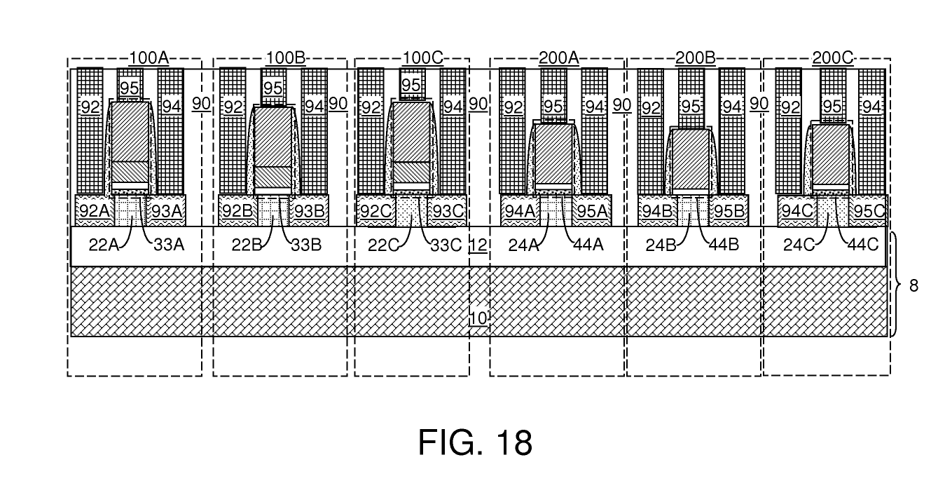

Referring to FIG. 18, a contact level dielectric layer 90 can be deposited over gate stacks, for example, by chemical vapor deposition (CVD) or spin-coating. The contact level dielectric layer 90 includes a dielectric material such as silicon oxide, silicon nitride, and/or organosilicate glass. Various contact via structures can be formed through the contact level dielectric layer 90. The various contact via structures can include, for example, source-side contact via structures 92, drain-side contact via structures 94, and gate-side contact via structures 95.

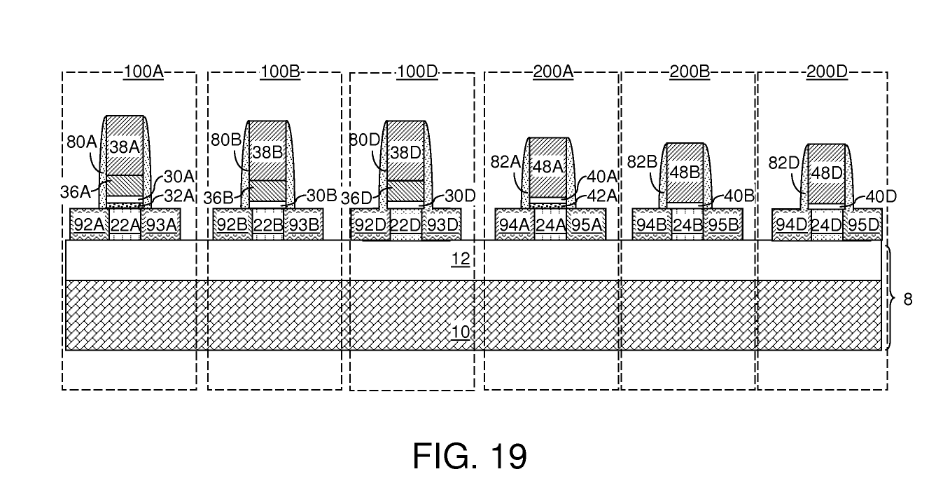

Referring to FIG. 19, a variation of the second exemplary semiconductor structure can be derived from the second exemplary semiconductor structure by adding a fourth first-type device region 100D and/or a fourth second-type device region 200D and by performing the processing steps of FIGS. 12-18. Alternatively, the fourth first-type device region 100D can substitute any of the first-type device regions (100A, 100B, 100C), and/or the fourth second-type device region 200D can substitute any of the second-type device regions (200A, 200B, 200C).

The fourth first-type device region 100D can include a fourth first-type channel region 22C having a same composition as a third channel region 22C (See FIG. 17). The fourth first-type device region 100D can further include a fourth first-type source region 92D having a same composition as a third source region 92C (See FIG. 17), and a fourth first-type drain region 93D having a same composition as a third drain region 93C (See FIG. 17). The fourth-type device region 100D can include a fourth first-type gate spacer 80D having a same composition and thickness as a third gate spacer 80C (See FIG. 17). The fourth first-type device region 100D can include a fourth first-type high-k gate dielectric layer 30D having a same composition as a second high-k gate dielectric layer 30B, a fourth first-work-function-material portion 36D having a same composition as a second first-work-function-material portion 36B, and a fourth first-type second-work-function-material portion 38D having a same composition as a second second-work-function-material portion 38B.

The fourth second-type device region 200D can include a fourth second-type channel region 24C having a same composition as a sixth channel region 24C (See FIG. 17). The fourth second-type device region 200D can further include a fourth second-type source region 94D having a same composition as a sixth source region 94C (See FIG. 17), and a fourth second-type drain region 95D having a same composition as a sixth drain region 95C (See FIG. 17). The fourth-type device region 200D can include a fourth second-type gate spacer 82D having a same composition and thickness as a sixth gate spacer 82C (See FIG. 17). The fourth second-type device region 200D can include a fourth second-type high-k gate dielectric layer 40D having a same composition as a fifth high-k gate dielectric layer 40B, a fourth first-work-function-material portion 36D having a same composition as a second first-work-function-material portion 36B, and a fourth second-type second-work-function-material portion 48D having a same composition as a fifth second-work-function-material portion 48B. The processing steps of FIG. 18 can be subsequently performed.

In one embodiment, at least two channel regions (22A, 22B, 22C, 24A, 24B, 24C) can be intrinsic semiconductor material regions, and fin field effect transistors having different threshold voltages can be formed without employing a doped channel region. In this case, by eliminating the doping of the channel regions, i.e., by employing intrinsic semiconductor materials as the semiconductor materials for channel regions, variations in the threshold voltage of the fin field effect transistors due to stochastic variations in the dopant distribution can be eliminated. A tighter distribution of threshold voltages can be provided for multiple types of field effect transistors of the same conductivity type, i.e., for each of p-type fin field effect transistors and n-type fin field effect transistors. If the at least two channel regions includes different semiconductor materials, e.g., silicon and a silicon-germanium alloy, the threshold voltages of multiple fin field effect transistors can be further tuned by selecting a suitable semiconductor material for each device.

In one embodiment, at least one channel region (22A, 22B, 22C, 24A, 24B, 24C) can be doped semiconductor material regions, and fin field effect transistors having different threshold voltages can be formed by adjusting the dopant concentration in the corresponding channel region (22A, 22B, 22C, 24A, 24B, 24C). The dopant type and the dopant concentration can be employed as additional tuning parameters to optimize the threshold voltage of corresponding fin field effect transistor(s).

While the present disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the present disclosure is intended to encompass all such alternatives, modifications and variations which fall within the scope and spirit of the present disclosure and the following claims.

What is claimed is:

1. A semiconductor structure comprising:
a first fin field effect transistor including a first gate stack that contains a first high dielectric constant (high-k) dielectric portion comprising a first high-k dielectric material straddling a first semiconductor fin, and a first gate electrode contacting said first high-k dielectric portion;
a second fin field effect transistor including a second gate stack that contains a threshold voltage adjustment oxide portion comprising another dielectric material different from said first high-k dielectric material and straddling a second semiconductor fin, a second high-k dielectric portion comprising said first high-k dielectric material, and a second gate electrode contacting said second high-k dielectric portion; and
a third fin field effect transistor including a third gate stack that contains a third high-k dielectric portion comprising said first high-k dielectric material and straddling a third semiconductor fin, and a third gate electrode contacting said third high-k dielectric portion, wherein said first and second fin field effect transistors are transistors of a first conductivity type, said third fin field effect transistor is a transistor of a second conductivity type that is the opposite of said first conductivity type.

2. The semiconductor structure of claim 1, wherein said first semiconductor fin comprises a first semiconductor material throughout, said second semiconductor fin comprises a second semiconductor material throughout, and said third semiconductor fin comprises a third semiconductor material throughout, wherein each of said first semiconductor material, said second semiconductor material, and said third semiconductor material is independently selected from single crystalline silicon, a single crystalline silicon-germanium alloy, a single crystalline silicon-carbon alloy, and a single crystalline silicon-germanium-carbon alloy.

3. The semiconductor structure of claim 1, wherein said third high-k dielectric portion contacts said third semiconductor fin.

4. The semiconductor structure of claim 3, further comprising a fourth fin field effect transistor including a fourth gate stack, wherein said fourth gate stack comprises, from bottom to top, another threshold voltage adjustment oxide portion comprising said another dielectric material and straddling a fourth semiconductor fin, a fourth high-k dielectric portion comprising said first high-k dielectric material, and a fourth gate electrode contacting said fourth high-k dielectric portion.

5. The semiconductor structure of claim 1, wherein said third fin field effect transistor comprises a third gate stack, wherein said third gate stack includes at least, from bottom to top, another threshold voltage adjustment oxide portion comprising said another dielectric material and contacting said third semiconductor fin, a third high-k dielectric portion comprising said first high-k dielectric material, and a third gate electrode contacting said third high-k dielectric portion.

6. The semiconductor structure of claim 5, further comprising a fourth fin field effect transistor including a fourth gate stack, wherein said fourth gate stack comprises, from bottom to top, yet another threshold voltage adjustment oxide portion comprising said another dielectric material and straddling a fourth semiconductor fin, a fourth high-k dielectric portion comprising said first high-k dielectric material, and a fourth gate electrode contacting said fourth high-k dielectric portion, wherein said third channel region and said fourth semiconductor channel portions are single crystalline intrinsic semiconductor material portions including different semiconductor materials.

7. The semiconductor structure of claim 1, wherein said first high-k dielectric material comprises a material selected from hafnium oxide, zirconium oxide, tantalum oxide, titanium oxide, silicates of thereof, and alloys thereof.

8. The semiconductor structure of claim 7, wherein said second high-k dielectric material comprises a material selected from an oxide of a Group IIA element, an oxide of a Group IIIB element, aluminum oxide, and alloys thereof.

9. The semiconductor structure of claim 1, wherein said first high-k dielectric portion does not include said second high-k dielectric material.

10. The semiconductor structure of claim 9, wherein said second high-k dielectric portion further comprises said another dielectric material, wherein an atomic concentration of said another dielectric material decreases with distance from an interface between said second semiconductor fin and said threshold voltage adjustment oxide portion.

11. A method of forming a semiconductor structure comprising:
forming a high dielectric constant (high-k) dielectric layer comprising a first high-k dielectric material on a plurality of semiconductor fins;
forming and patterning a diffusion barrier metallic nitride layer, wherein at least one portion of said high-k dielectric layer is physically exposed while at least another portion of said high-k dielectric layer is covered by a patterned portion of said diffusion barrier metallic nitride layer;
forming a threshold voltage adjustment oxide layer comprising a second high-k dielectric material over said high-k dielectric layer and said patterned diffusion barrier metallic nitride layer;
inducing diffusion of said second high-k dielectric material through said first high-k dielectric material by an anneal, wherein said patterned diffusion barrier layer blocks diffusion of said second high-k dielectric material therethrough and at least one threshold voltage adjustment oxide portion is formed directly on at least one of said plurality of semiconductor material stacks;
removing said patterned diffusion barrier metallic nitride layer;
forming at least one conductive material layer on said high-k dielectric layer; and
forming gate stacks by patterning said at least one conductive material layer, said high-k dielectric layer, and said at least one threshold voltage adjustment oxide portion.

12. The method of claim 11, further comprising:
forming a cap material layer directly on said patterned diffusion barrier metallic nitride layer prior to said anneal; and
removing said cap material layer after said anneal.

13. The method of claim 12, wherein a portion of said cap material layer is deposited directly on said threshold voltage adjustment oxide layer.

14. The method of claim 12, wherein said cap material layer comprises at least one of a metallic material layer and a semiconductor material layer.

15. The method of claim 11, further comprising:
forming a first fin field effect transistor including a first gate stack, wherein said first gate stack includes, from bottom to top, a first high dielectric constant (high-k) dielectric portion comprising said first high-k dielectric material and contacting a first semiconductor fin among said plurality of semiconductor fins, and a first gate electrode contacting said first high-k dielectric portion;
forming a second fin field effect transistor including a second gate stack, wherein said second gate stack includes, from bottom to top, a threshold voltage adjustment oxide portion comprising said second high-k dielectric material and contacting a second semiconductor fin among said plurality of semiconductor fins, a second high-k dielectric portion comprising said first high-k dielectric material, and a second gate electrode contacting said second high-k dielectric portion.

16. The method of claim 15, wherein each of said first semiconductor fin and said second semiconductor fin are intrinsic semiconductor material portions.

17. The method of claim 15, further comprising forming a third fin field effect transistor including a third gate stack, wherein said third gate stack includes at least, from bottom to top, a third high-k dielectric portion comprising said first high-k dielectric material and straddling a third semiconductor fin among said plurality of semiconductor fins, and a third gate electrode contacting said third high-k dielectric portion, wherein said first fin field effect transistor and said third fin field effect transistors are transistors of complementary types.

18. The method of claim 17, wherein said first semiconductor fin comprises a first semiconductor material throughout, said second semiconductor fin comprises a second semiconductor material throughout, and said third semiconductor fin comprises a third semiconductor material throughout, and wherein each of said first semiconductor material, said second semiconductor material, and said third semiconductor material is independently selected from single crystalline silicon, a single crystalline silicon-germanium alloy, a single crystalline silicon-carbon alloy, and a single crystalline silicon-germanium-carbon alloy.

19. The method of claim 11, wherein said first high-k dielectric material comprises a material selected from hafnium oxide, zirconium oxide, tantalum oxide, titanium oxide, silicates of thereof, and alloys thereof.

20. The method of claim 19, wherein said second high-k dielectric material comprises a material selected from an oxide of a Group IIA element, an oxide of a Group MB element, aluminum oxide, and alloys thereof.
